(19) United States
(12) Patent Application Publication
(10) Pub. No.: US 2018/0366546 A1
(43) Pub. Date: Dec. 20, 2018

(54) FINFET DEVICE WITH STACKED GERMANIUM AND SILICON CHANNEL

(71) Applicant: Taiwan Semiconductor Manufacturing Co., Ltd., Hsin-Chu (TW)

(72) Inventors: Cheng-Han SUNG, Hsin-Chu (TW); Ya-Tang Chiang, Hsin-Chu (TW)

(21) Appl. No.: 15/628,256

(22) Filed: Jun. 20, 2017

(51) Int. Cl. H01L 29/10; H01L 29/78; H01L 29/165; H01L 29/66

(52) U.S. Cl. CPC H01L 29/1054; H01L 29/785; H01L 29/66795; H01L 29/66545; H01L 29/165

(57) ABSTRACT

A semiconductor device includes a fin-like structure. The fin-like structure includes a bottom layer formed of silicon and at least a top layer formed of germanium. The semiconductor device further includes a gate stack feature overlaying a central upper portion of the fin-like structure, wherein the gate stack is in contact with a top surface and sidewalls of the top layer, and at least part of sidewalls of the bottom layer.

### BACKGROUND

Integrated circuits (IC's) typically include a large number of components, particularly transistors. One type of transistor is a metal-oxide-semiconductor field-effect-transistor (MOSFET). MOSFET devices typically include a gate structure on top of a semiconductor substrate. Both sides of the gate structure are doped to form source and drain regions. A channel is formed between the source and drain regions beneath the gate. Based on a voltage bias applied to the gate, electric current may either be allowed to flow through the channel or be inhibited from doing so.

In some cases, the channel may be formed as a fin-like structure (herein “fin”). Such a fin protrudes beyond a top surface of the substrate and runs perpendicular to the gate structure formed on the substrate and the fin. In general, a field-effect-transistor using such a fin as a channel is referred to as a fin field-effect-transistor (“FinFET”). In terms of materials used to form the fin channel, germanium, or its alloy (e.g., silicon-germanium), is generally considered as an alternative material to silicon because of germanium's higher electron and hole mobilities, when compared to silicon.

Conventionally, a relatively thick germanium layer is typically formed to surround a pre-formed silicon fin channel, i.e., overlaying the silicon fin channel's top surface and sidewalls, to effectively integrate germanium or its alloy into the fin channel. However, such approaches may induce various issues such as, for example, defects formed at interfaces between the silicon fin channel and the germanium layer due to a lattice mismatch between silicon and germanium. Those defects may disadvantageously affect overall performance of the respective FinFET, for example, a larger leakage current, a poorer gate controllability, etc. Thus, conventional techniques to make a fin channel of a FinFET that includes germanium or its alloy are not entirely satisfactory.

### BRIEF DESCRIPTION OF THE DRAWINGS

Aspects of the present disclosure are best understood from the following detailed description when read with the accompanying figures. It is noted that various features are not necessarily drawn to scale. In fact, the dimensions and geometries of the various features may be arbitrarily increased or reduced for clarity of discussion.

FIG. 1 illustrates a flow chart of an embodiment of a method to form a semiconductor device, in accordance with some embodiments.

FIGS. 2A, 3A, 4A, 5A, 6A, 7A, 8A, 9A, 10A, 11A, 12A, and 13A illustrate perspective views of an exemplary semiconductor device, made by the method of FIG. 1, during various fabrication stages, in accordance with some embodiments.

FIG. 2B, 3B, 4B, 5B, 6B, 7B, 8B, 9B, 10B, 11B, 12B, and 13B illustrate corresponding cross-sectional views of FIGS. 2A, 3A, 4A, 5A, 6A, 7A, 8A, 9A, 10A, 11A, 12A, and 13A, in accordance with some embodiments.

FIG. 14 illustrates a cross-sectional view of another exemplary device, made by the method of FIG. 1, at one of the various stages of fabrication, in accordance with some embodiments.

### DETAILED DESCRIPTION OF EXEMPLARY EMBODIMENTS

The following disclosure describes various exemplary embodiments for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides various embodiments of a fin field-effect-transistor (FinFET) that includes a fin-like channel formed of a silicon (Si) layer and at least one germanium (Ge), or germanium alloy (e.g., silicon-germanium (Si₁₋ₓGeₓ, wherein x represents a molar ratio of the Ge)), layer and method of forming the same. In some embodiments, the Si layer may be formed as a bottom layer of the fin-like channel, and the at least one Ge, or Si₁₋ₓGeₓ, layer may be formed as a top layer capping the Si bottom layer of the fin-like channel. In some other embodiments, while the Si layer is still formed as the bottom layer of the fin-like channel, the fin-like channel may include plural top layers that are stacked on top of one another and each formed of a respective material selected from: Si, Ge, and Si₁₋ₓGeₓ. As such, the fin-like channel including the bottom Si layer and the plural top layers may be formed as a superlattice structure. By using such a “stacked” structure (e.g., a Si bottom layer capped by a Ge or Si₁₋ₓGeₓ layer, a superlattice structure, etc.) to incorporate Ge or Si₁₋ₓGeₓ, into a Si fin-like channel, respective thickness of each of the top layers can be accurately controlled, which may eliminate the formation of latch mismatch at any interface between Si and Ge layers, and/or Si and Si₁₋ₓGeₓ layers. As such, the above-mentioned issues may be advantageously avoided. Moreover, because of the adding of Ge or Si₁₋ₓGeₓ, which presents higher mobilities than Si, into the fin-like channel, overall performance (e.g., a turn-on current, a gate controllability, etc.) of the disclosed FinFET may be substantially improved.

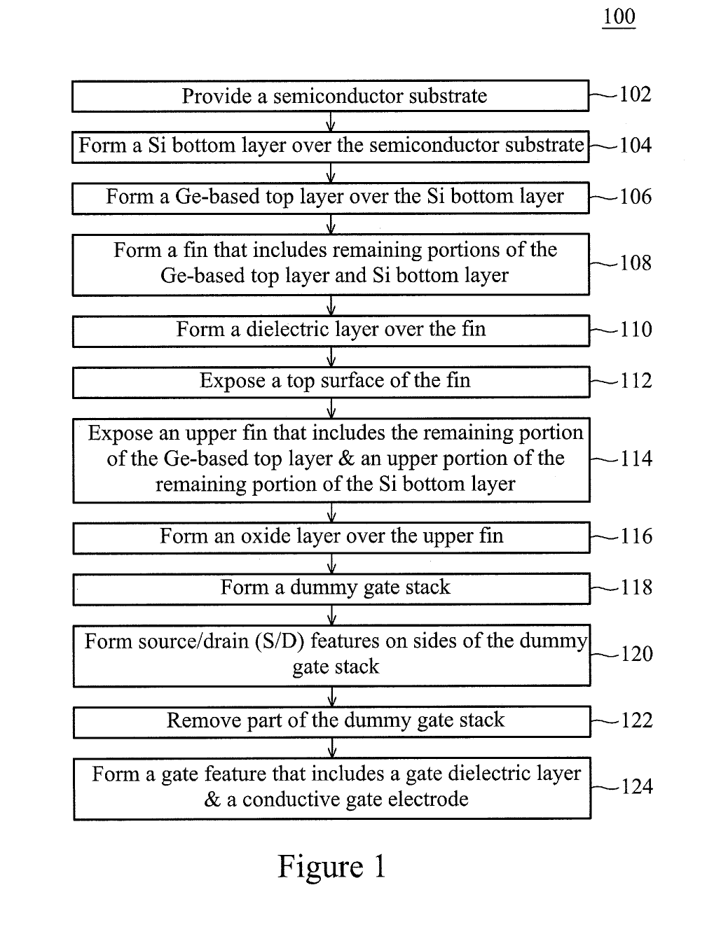

FIG. 1 illustrates a flowchart of a method 100 to form a semiconductor device according to one or more embodiments of the present disclosure. It is noted that the method 100 is merely an example, and is not intended to limit the present disclosure. In some embodiments, the semiconductor device is, at least part of, a FinFET. As employed by the present disclosure, the FinFET refers to any fin-based, multi-gate transistor. It is noted that the method of FIG. 1 does not produce a completed FinFET. A completed FinFET may be fabricated using complementary metal-oxide-semiconductor (CMOS) technology processing. Accordingly, it is understood that additional operations may be provided before, during, and after the method 100 of FIG. 1, and that some other operations may only be briefly described herein.

In some embodiments, the method 100 starts with operation 102 in which a semiconductor substrate is provided. The method 100 continues to operation 104 in which a bottom layer that includes Si (hereinafter “Si bottom layer”) is formed on the semiconductor substrate. The method 100 continues to operation 106 in which at least one top layer that includes Ge or Si₁₋ₓGeₓ (hereinafter “Ge-based top layer”), is formed over the Si bottom layer. The method 100 continues to operation 108 in which a fin is formed extending beyond a major surface of the semiconductor substrate. According to some embodiments, such a fin is formed through one or more etching processes, respectively or concurrently, performed on the Ge-based top layer and the Si bottom layer, and accordingly, the fin includes respective remaining portions of the Si bottom layer and the at least one Ge-based top layer. More specifically, respective sidewalls of the remaining portions of the Si bottom layer and the at least one Ge-based top layer are exposed once the fin is formed. The method 100 continues to operation 110 in which a dielectric material is deposited over the semiconductor substrate. The method 100 continues to operation 112 in which a top surface of the fin is exposed. The method 100 continues to operation 114 in which an upper fin of the fin is exposed. According to some embodiments, such an upper fin includes an upper portion of the remaining portion of the Si bottom layer, and the remaining portion of the Ge-based top layer formed in operation 108. The method 100 continues to operation 116 in which an oxide layer is formed over the exposed upper fin. The method 100 continues to operation 118 in which a dummy gate stack is formed over respective central portions of the oxide layer and the upper fin. The method 100 continues to operation 120 in which source/drain (S/D) features are respectively formed on sides of the dummy gate stack. The method 100 continues to operation 122 in which at least part of the dummy gate stack and the central portion of the oxide layer are, respectively or concurrently, removed to expose the central portion of the upper fin. The method 100 continues to operation 124 in which a gate feature, including a gate dielectric layer and a conductive gate electrode, is formed over the exposed central portion of the upper fin.

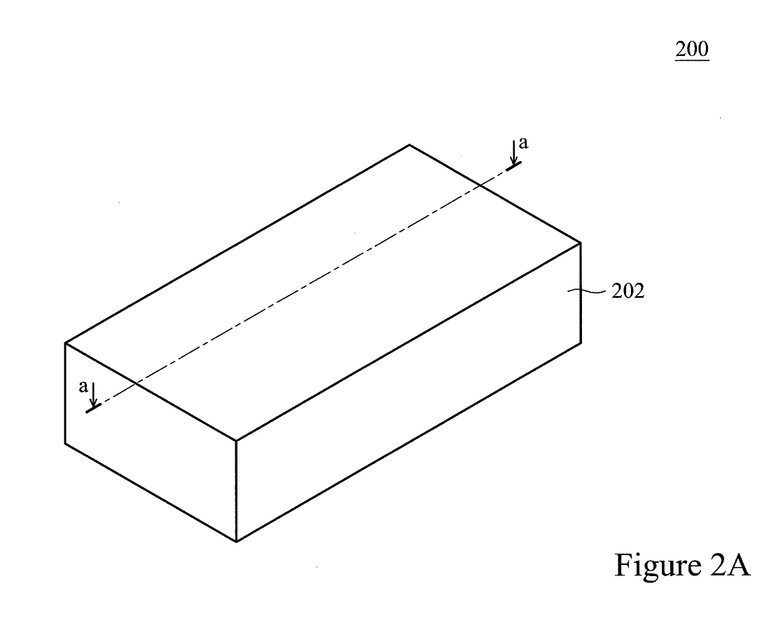

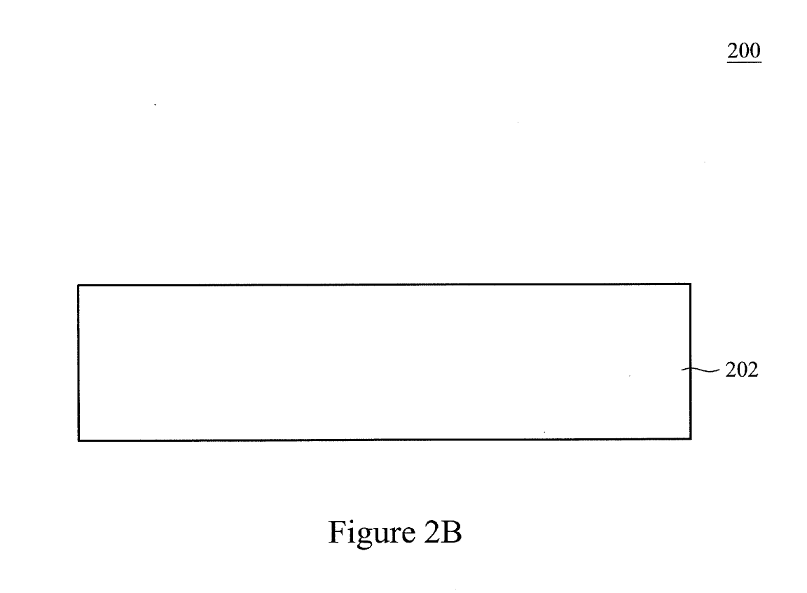

In some embodiments, operations of the method 100 may be associated with perspective views of a semiconductor device 200 at various fabrication stages as shown in FIGS. 2A, 3A, 4A, 5A, 6A, 7A, 8A, 9A, 10A, 11A, 12A, and 13A, respectively, and corresponding cross-sectional views as shown in FIGS. 2B, 3B, 4B, 5B, 6B, 7B, 8B, 9B, 10B, 11B, 12B, and 13B. In some embodiments, the semiconductor device 200 may be a FinFET. The FinFET 200 may be included in a microprocessor, memory cell, and/or other integrated circuit (IC). Also, FIGS. 2A through 12B are simplified for a better understanding of the concepts of the present disclosure. For example, although the figures illustrate the FinFET 200, it is understood the IC may comprise a number of other devices comprising resistors, capacitors, inductors, fuses, etc., which are not shown in FIGS. 2A through 12B, for purposes of clarity of illustration.

Corresponding to operation 102 of FIG. 1, FIG. 2A is a perspective view of the FinFET 200 including a substrate 202 at one of the various stages of fabrication, according to some embodiments, and FIG. 2B is a cross-sectional view of the FinFET 200 taken along line a-a of FIG. 2A. In some embodiments, the substrate 202 comprises a crystalline Si substrate (e.g., wafer). In some alternative embodiments, the substrate 202 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. Further, the substrate 202 may include a silicon-on-insulator (SOI) structure.

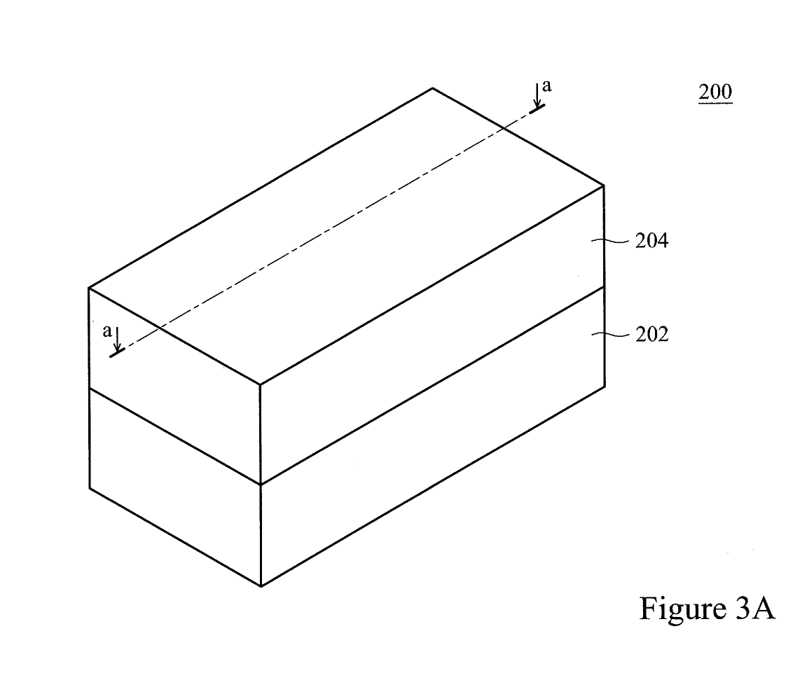

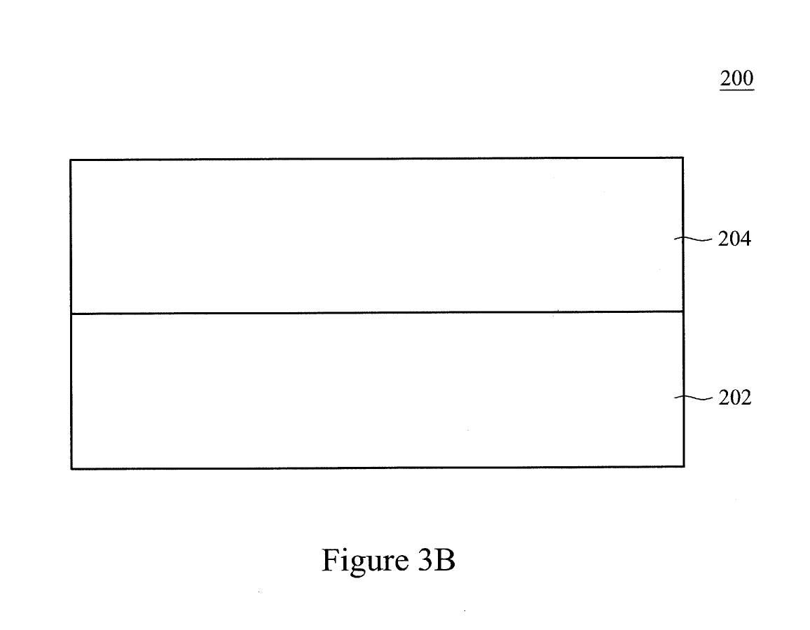

Corresponding to operation 104 of FIG. 1, FIG. 3A is a perspective view of the FinFET 200 including a bottom layer 204 formed over the substrate 202 at one of the various stages of fabrication, according to some embodiments, and FIG. 3B is a cross-sectional view of the FinFET 200 taken along line a-a of FIG. 3A. In some embodiments, the bottom layer 204 includes crystalline Si, hereinafter “Si bottom layer 204.” In some embodiments, the Si bottom layer 204 may be epitaxially grown by a CMOS compatible epitaxial process. The epitaxial process may include chemical vapor deposition (CVD) technique such as vapor-phase epitaxy (VPE), and/or other suitable processes known in the art, e.g., molecular beam epitaxy (MBE) technique, wafer bonding technique, etc. The epitaxial process may use suitable gaseous (or liquid) precursors to form the Si bottom layer 204, e.g., silane (SiH₄).

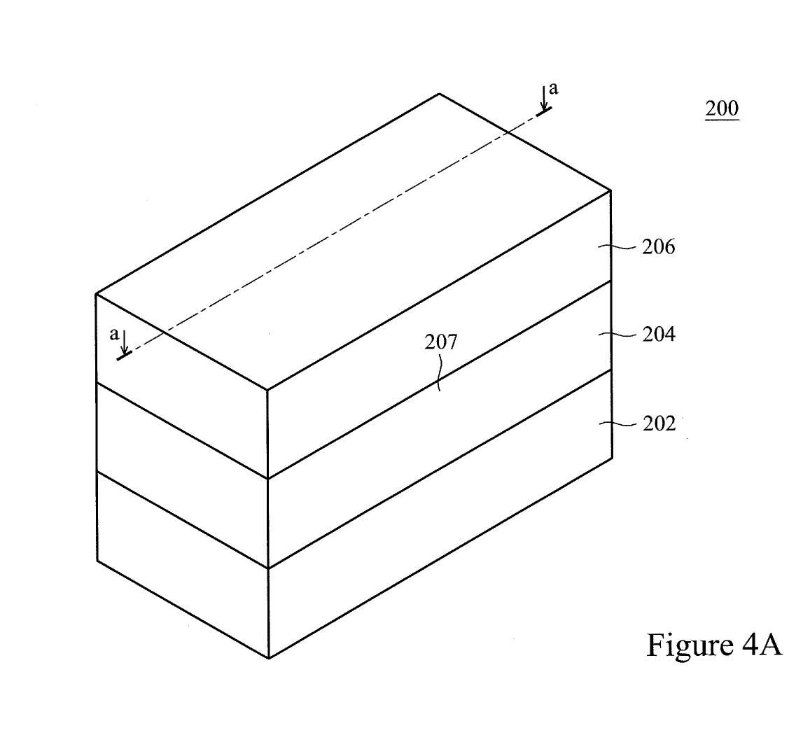

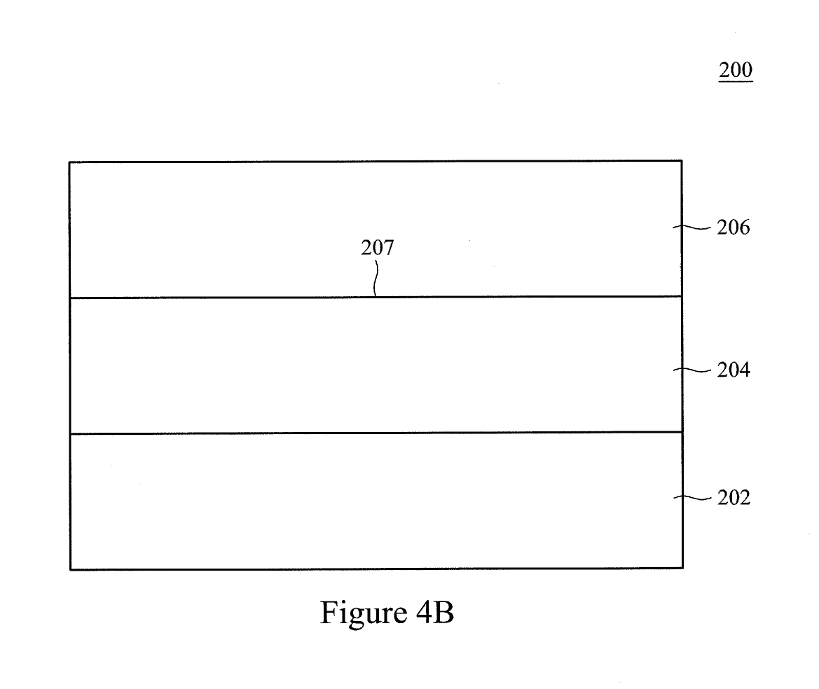

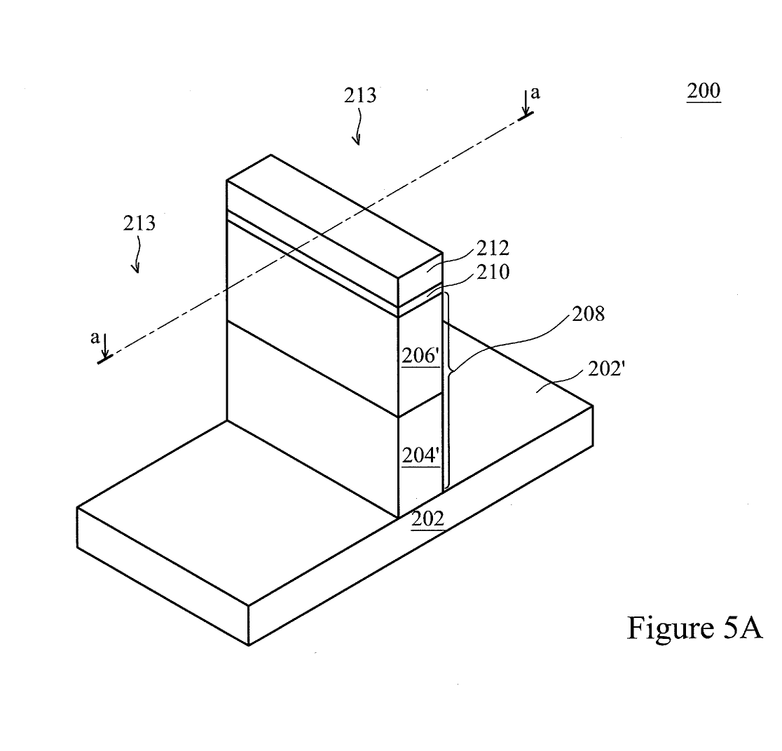

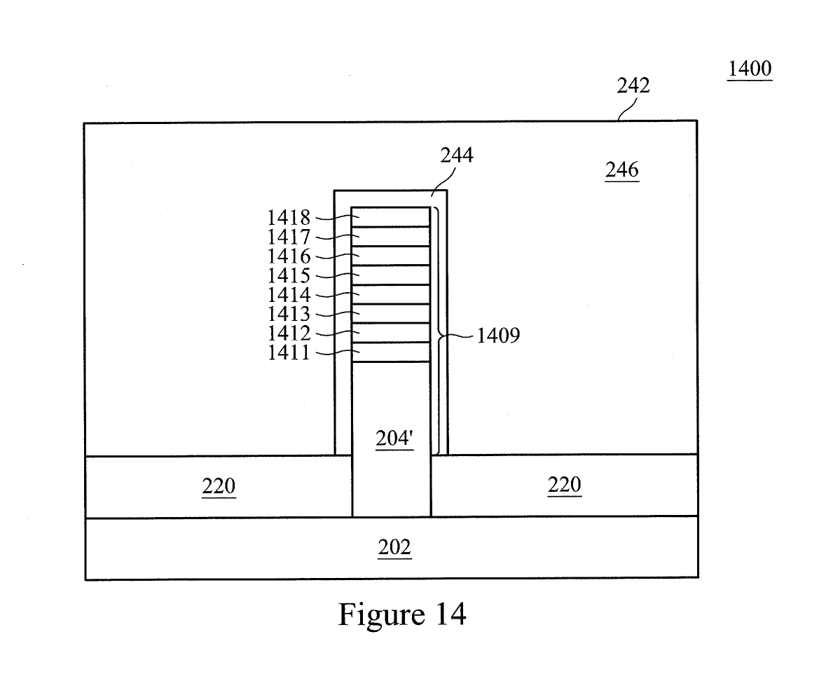

Corresponding to operation 106 of FIG. 1, FIG. 4A is a perspective view of the FinFET 200 including a top layer 206 formed over the Si bottom layer 204 at one of the various stages of fabrication, according to some embodiments, and FIG. 4B is a cross-sectional view of the FinFET 200 taken along line a-a of FIG. 4A. In some embodiments, the top layer 206 includes crystalline Ge, or Si₁₋ₓGeₓ, wherein “x” represents a molar ratio of Ge in such a Si₁₋ₓGeₓ top layer 206. Thus, the top layer 206 is herein referred to as “Ge-based top layer 206”. Although in the illustrative embodiments of FIGS. 4A and 4B (and the following figures), the Ge-based top layer 206 is shown as a single layer, in some alternative embodiments, the Ge-based top layer 206 may include a plurality of Si/Ge/Si₁₋ₓGeₓ layers stacked on top of one another, which will be described in further detail below with respect to FIG. 14.

Similar to the Si bottom layer 204, in some embodiments, the Ge-based top layer 206 may be epitaxially grown by the CMOS compatible epitaxial process. The epitaxial process may include chemical vapor deposition (CVD) technique such as vapor-phase epitaxy (VPE), and/or other suitable processes known in the art, e.g., molecular beam epitaxy (MBE) technique, wafer bonding technique, etc. The epitaxial process may use suitable gaseous (or liquid) precursors to form the Ge-based top layer 206. More specifically, when the Ge-based top layer 206 includes Ge, at least one of the gaseous precursors used during the epitaxial process includes germane (GeH₄); and when the Ge-based top layer 206 includes Si₁₋ₓGeₓ, both the gaseous precursors SiH₄ and GeH₄ may be concurrently used during the epitaxial process.

As mentioned above, in accordance with various embodiments of the present disclosure, the respective thickness of each of the Si bottom layer 204 and the Ge-based top layer 206 can be accurately controlled to avoid the lattice mismatch between the Si bottom layer 204 and the Ge-based top layer 206 so as to eliminate the presence of defects to be formed at interface 207 between the Si bottom layer 204 and the Ge-based top layer 206. In some embodiments, when the Ge-based top layer 206 is formed of Ge, the thickness of the Ge-based top layer 206 can be formed up to about 3 nanometers (nm) while the Si bottom layer 204 can be formed to have any desired thickness, e.g., about 30-100 nm; and when the Ge-based top layer 206 is formed of Si₁₋ₓGeₓ, the thickness of the Ge-based top layer 206 can be formed up to about 100 nm while the Si bottom layer 204 can be formed to have any desired thickness, e.g., about 30-100 nm.

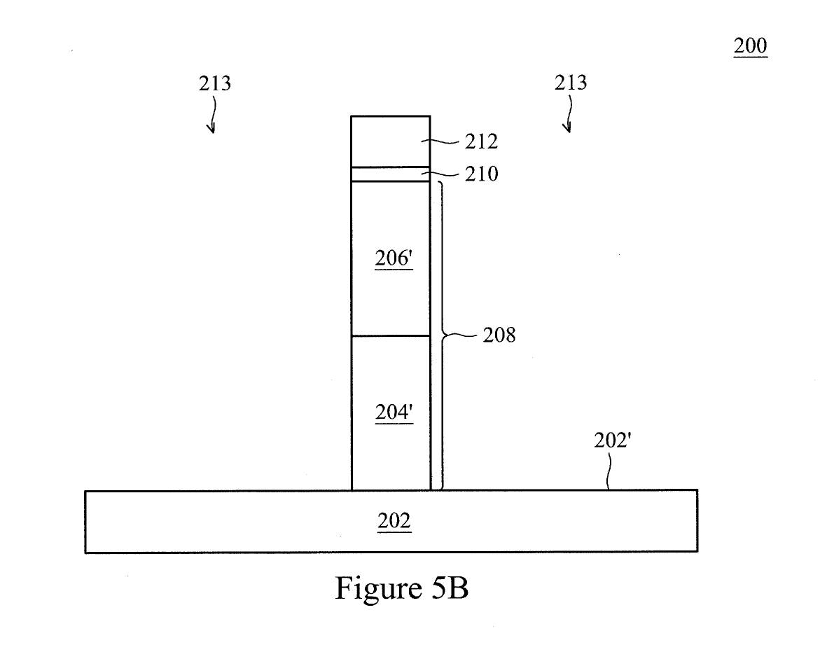

Corresponding to operation 108 of FIG. 1, FIG. 5A is a perspective view of the FinFET 200 including a fin 208 at one of the various stages of fabrication, according to some embodiments, and FIG. 5B is a cross-sectional view of the FinFET 200 taken along line a-a of FIG. 5A. As shown, the fin 208, including a remaining portion of the Si bottom layer 204′ and a remaining portion of the Ge-based top layer 206′, protrudes beyond a major surface 202′ of the semiconductor substrate 202. In other words, when the fin 208 is formed at operation 108, the major surface 202′, and respective sidewalls of the remaining portions of the Si bottom layer 204′ and the Ge-based top layer 206′ are exposed, in accordance with some embodiments.

In some embodiments, the fin 208 is formed by at least some of the following processes. A pad layer (e.g., formed of silicon oxide) 210 and a mask layer (e.g., formed of silicon nitride) 212 with a pattern 213 (e.g., openings 213) are formed over the Ge-based top layer 206 (FIG. 4A). The underlying Ge-based top layer 206 and Si bottom 204 are respectively or concurrently etched through such openings 213 so as to cause the major surface 202′ of the semiconductor substrate 202 and respective sidewalls of the remaining portions of the Si bottom layer 204′ and the Ge-based top layer 206 to be exposed, i.e., forming the fin 208. It is noted that although only one fin 208 is shown in the illustrated embodiments of FIGS. 5A and 5B (and the following figures), any desired number of fins may be formed on the semiconductor substrate 202 using a corresponding pattern of the pad layer 210 and the mask layer 212 while remaining within the scope of the present disclosure. After the fin 208 is formed, subsequently, a cleaning process may be performed to remove a native oxide of the semiconductor substrate 202. The cleaning may be performed using diluted hydrofluoric (DHF) acid, or the like.

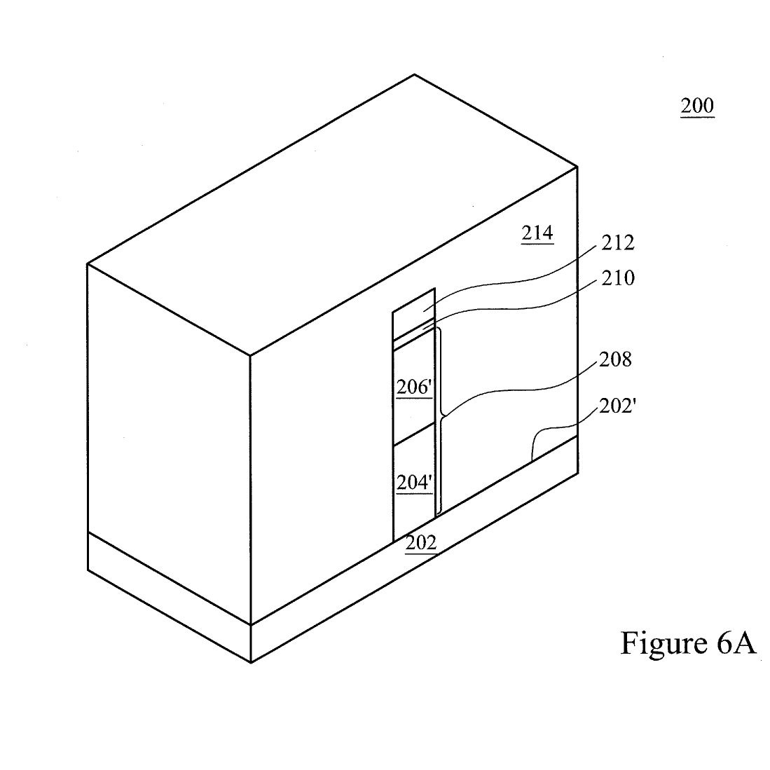

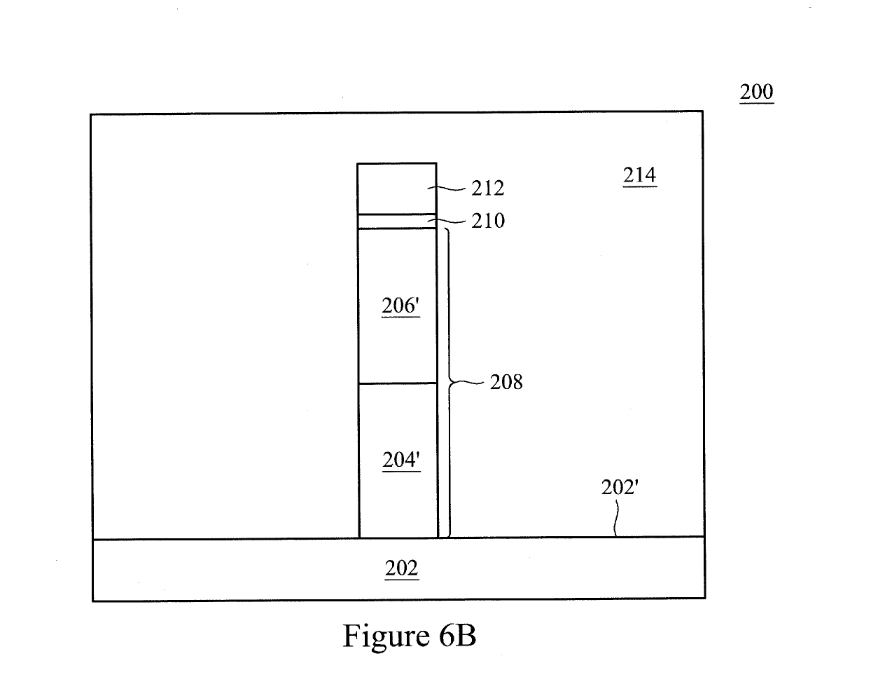

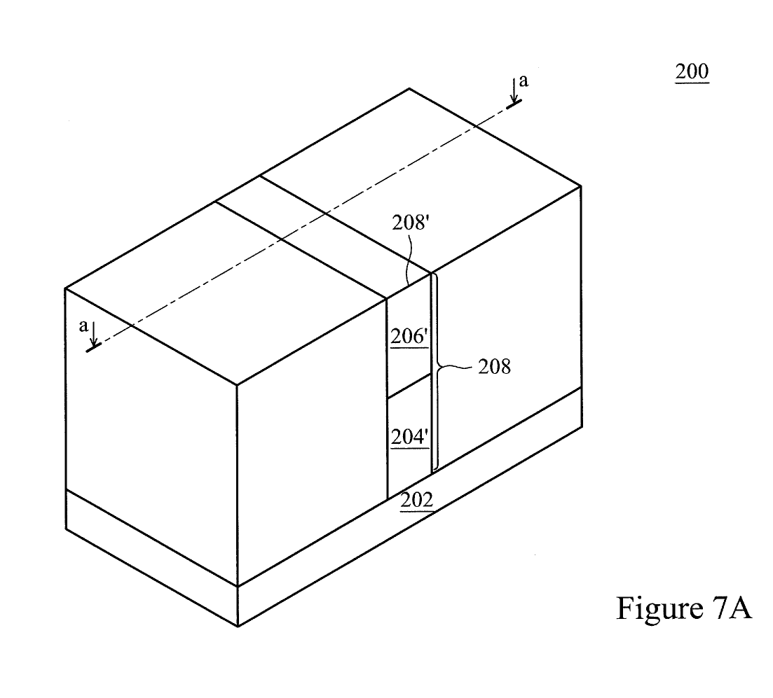

Corresponding to operation 110 of FIG. 1, FIG. 6A is a perspective view of the FinFET 200 including a dielectric material 214 formed over the semiconductor substrate 202, the fin 208, the pad layer 210, and the mask layer 212 at one of the various stages of fabrication corresponding to operation 108 of FIG. 1A, according to some embodiments, and FIG. 6B is a cross-sectional view of the FinFET 200 taken along line a-a of FIG. 6A. As shown, the dielectric material 214 is formed over the while FinFET 200 such that the major surface 202′, and respective sidewalls of the remaining portions of the Si bottom layer 204′ and the Ge-based top layer 206′ are overlaid by the dielectric material 214.

In one embodiment, the dielectric material 214 may be deposited over the semiconductor substrate 202 using a high-density-plasma (HDP) CVD process with reacting precursors, e.g., silane (SiH₄) and oxygen (O₂). In another embodiment, the dielectric material 214 may be deposited over the semiconductor substrate 202 using a sub-atmospheric CVD (SACVD) process or a high aspect-ratio process (HARP), wherein process gases used in such processes may comprise tetraethylorthosilicate (TEOS) and ozone (O₃). In yet another embodiment, the dielectric material 214 may be deposited over the semiconductor substrate 202 using a spin-on-dielectric (SOD) process such as, for example, hydrogen silsesquioxane (HSQ), methyl silsesquioxane (MSQ), or the like.

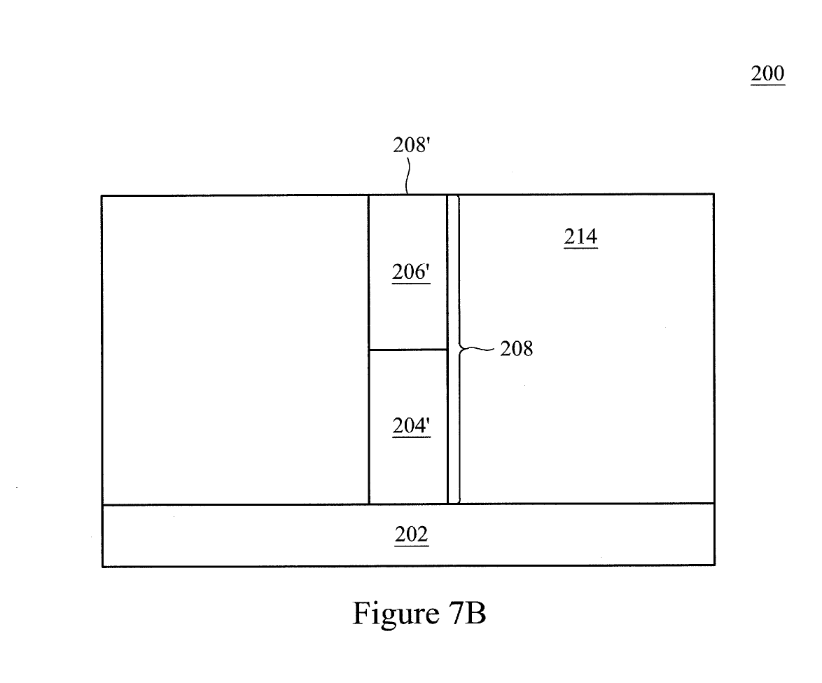

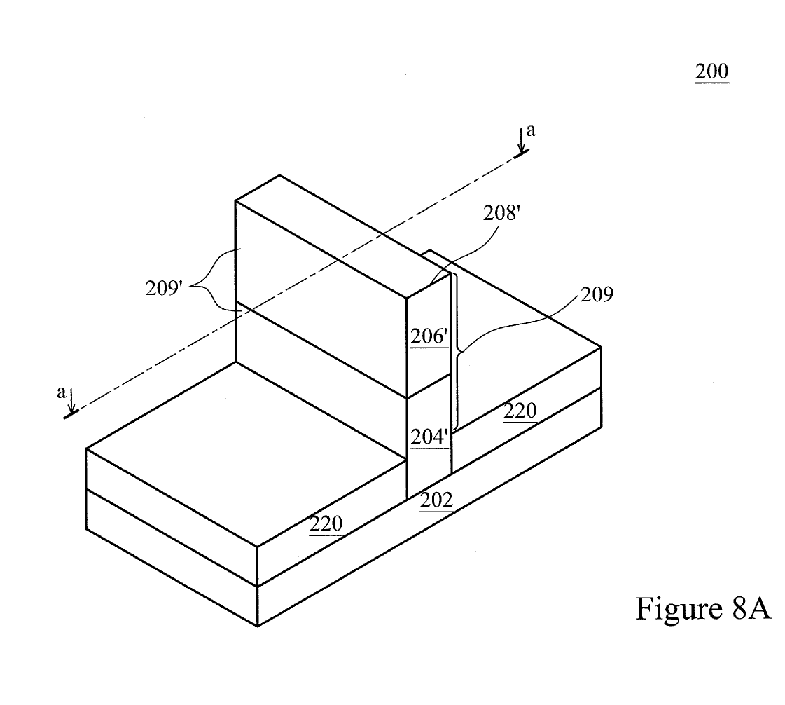

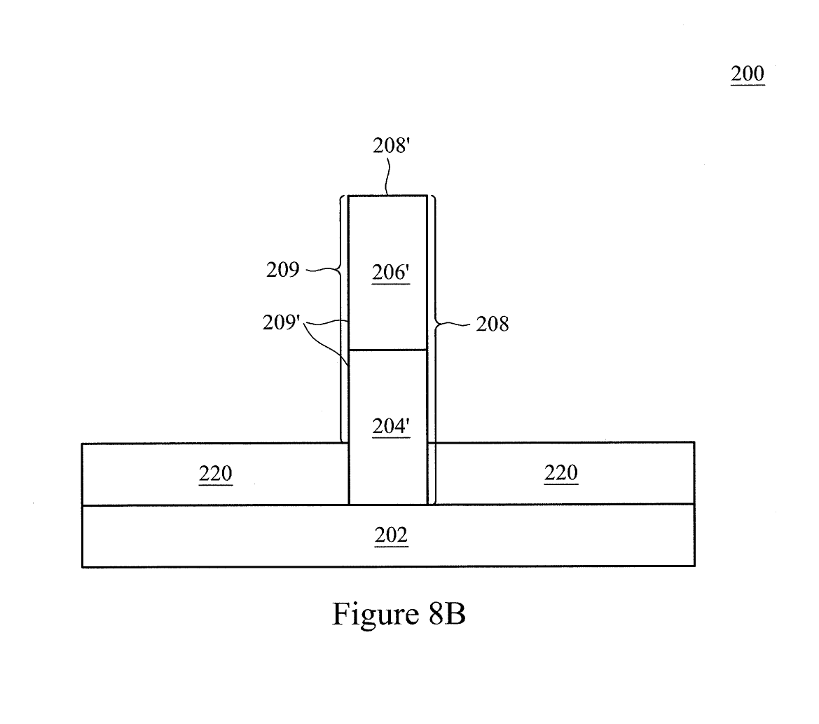

Corresponding to operation 112 of FIG. 1, FIG. 7A is a perspective view of the FinFET 200 including a top surface 208′ of the fin 208 being exposed, according to some embodiments, and FIG. 7B is a cross-sectional view of the FinFET 200 taken along line a-a of FIG. 7A. In some embodiments, the top surface 208′ is exposed by performing a polishing process (e.g., a chemical-mechanical polishing process) on the dielectric material 214 (FIGS. 6A and 6B) until the mask layer 212 is again exposed. The mask layer 212 and the pad layer 210 are then removed to expose the top surface 208′. In some embodiments, when the mask layer 212 is formed of silicon nitride, the mask layer 212 may be removed using a wet process using hot phosphoric acid (H₃PO₄), and when the pad layer 210 is formed of silicon oxide, the pad layer 210 may be removed using diluted hydrofluoric acid (HF). In some alternative embodiments, the removal of the mask layer 212 and the pad layer 210 may be performed after a recession process performed on the dielectric material 214, which will be discussed in FIGS. 8A and 8B below.

Corresponding to operation 114 of FIG. 1, FIG. 8A is a perspective view of the FinFET 200 including a respective upper fin 209 being exposed, according to some embodiments, and FIG. 8B is a cross-sectional view of the FinFET 200 taken along line a-a of FIG. 8A. As shown, isolation features 220 are respectively formed around a lower portion of the fin 208 so that the exposed upper fin 209 includes an upper portion of the remaining portion of the Si bottom layer 204′ and the remaining portion of the Ge-based top layer 206′. In some embodiments, after the upper fin 209 is exposed, sidewalls 209′ of the upper fin 209, which includes respective sidewalls of the upper portion of the remaining portion of the Si bottom layer 204′ and the remaining portion of the Ge-based top layer 206′, are exposed together with the respective top surfaces 208′.

In some embodiments, the isolation feature 220 may be formed by performing at least one etching process to recess an upper portion of the dielectric material 214 (FIGS. 7A and 7B). In an embodiment, the etching process may include performing a wet etching process such as, for example, dipping the semiconductor substrate 202 in a hydrofluoric acid (HF) solution to recess the upper portion of the dielectric material 214 until the upper fin 209 is exposed. In another embodiment, the etching process may include performing a dry etching process such as, for example, using etching gases fluoroform (CHF₃) and/or boron trifluoride (BF₃) to recess the upper portion of the dielectric material 214 until the upper fin 209 is exposed.

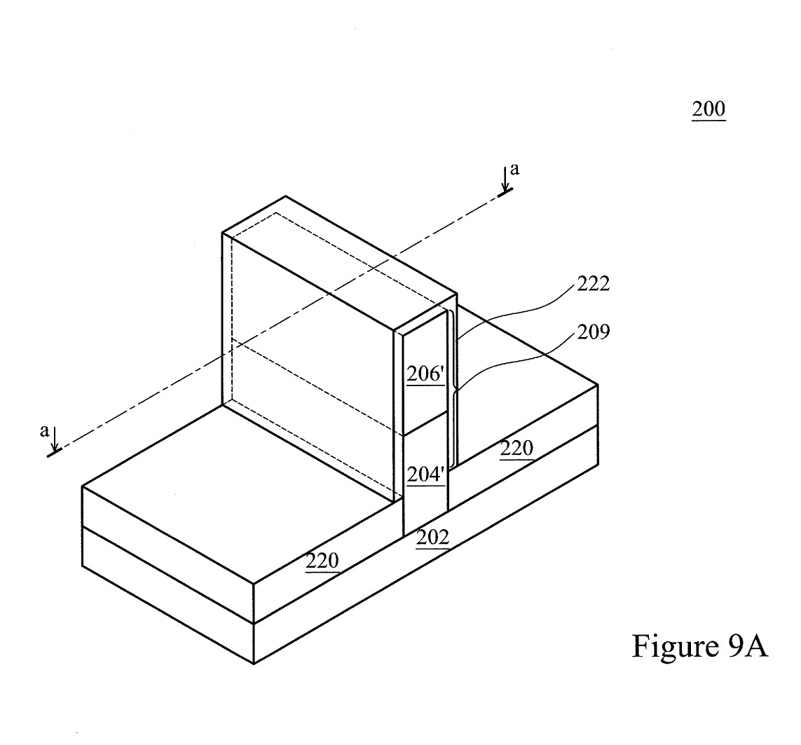

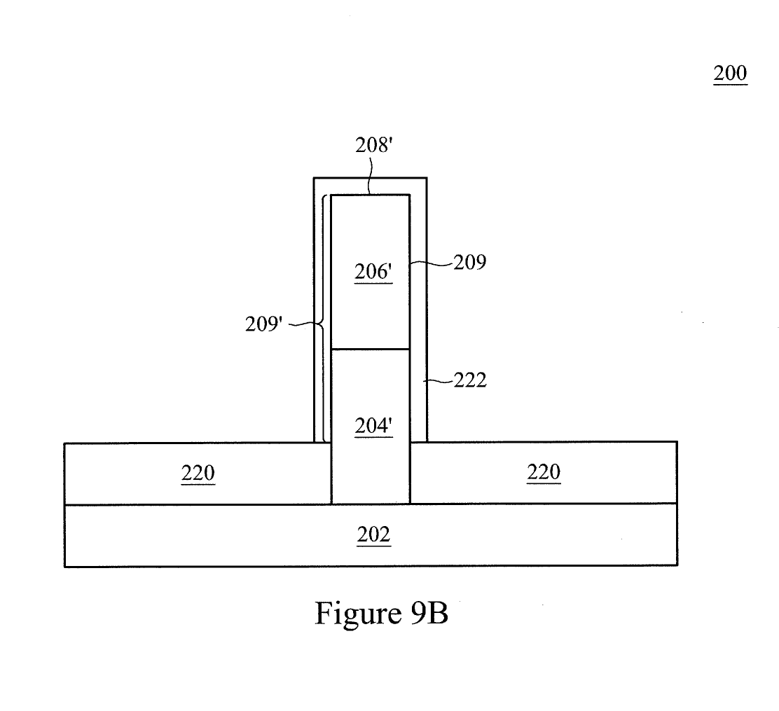

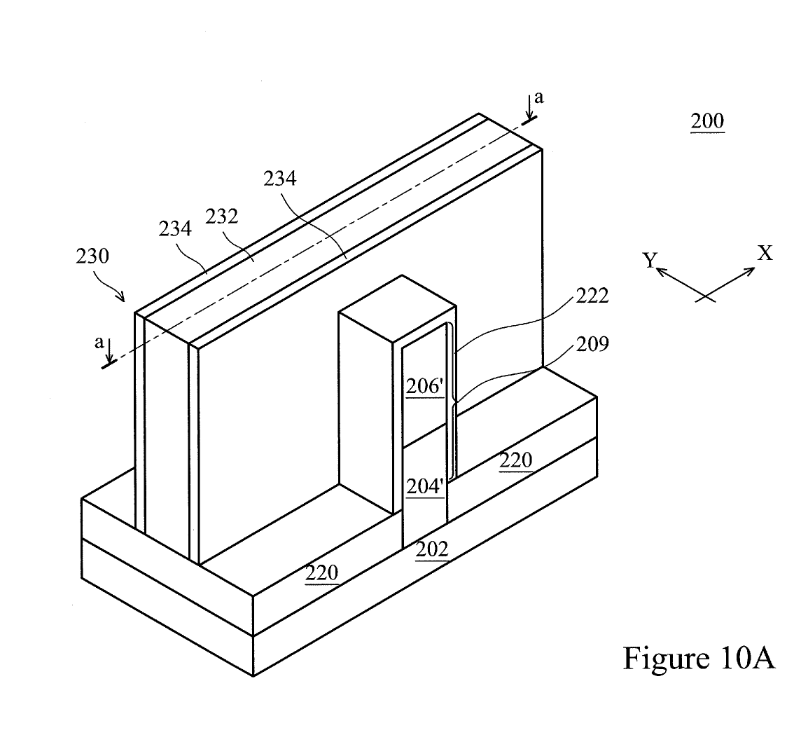

Corresponding to operation 116 of FIG. 1, FIG. 9A is a perspective view of the FinFET 200 including an oxide layer 222 overlaying the upper fin 209, according to some embodiments, and FIG. 9B is a cross-sectional view of the FinFET 200 taken along line a-a of FIG. 9A. As shown, the oxide layer 222 is formed to extend along the sidewalls 209′ and overlay the top surface 208′ of the upper fin 209. In some embodiments, the oxide layer (e.g., formed of silicon oxide) 222 may be formed by using a thermal oxidation process, an atomic layer deposition (ALD) process, a chemical vapor deposition (CVD) process, or the like.

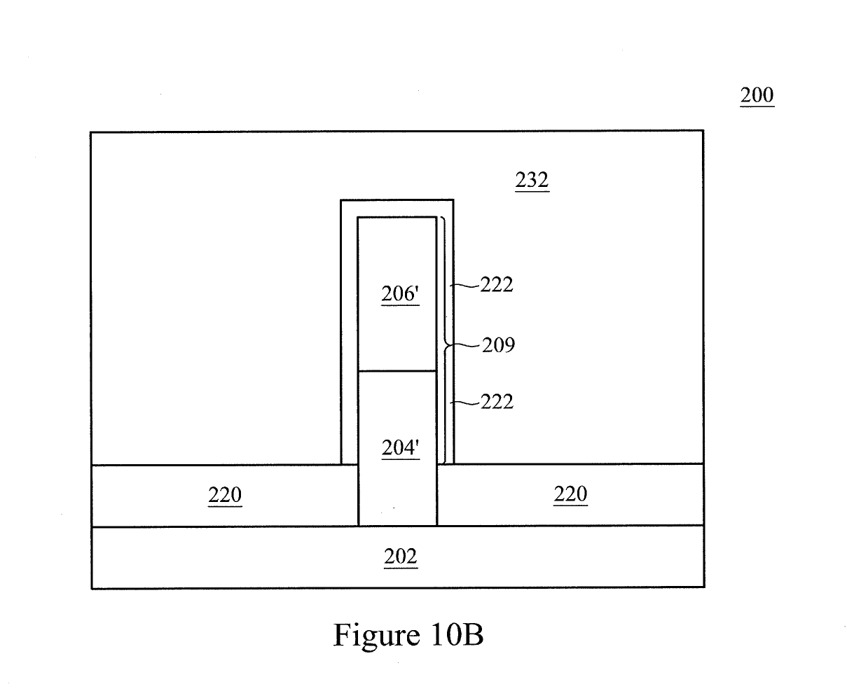

Corresponding to operation 118 of FIG. 1, FIG. 10A is a perspective view of the FinFET 200 including a dummy gate stack 230 extending along the X direction so as to overlay the upper fin 209, and the Y direction so as to overlay respective central portions of the upper fin 209 and the oxide layer 222, according to some embodiments, and FIG. 10B is a cross-sectional view of the FinFET 200 taken along line a-a of FIG. 10A. As shown, the dummy gate stack 230 is formed to overlay the central portion of the upper fin 209 with the respective central portion of the oxide layer 222 being sandwiched therebetween.

In some embodiments, the central portion of the upper fin 209, overlaid by the dummy gate stack 230, may serve as a conduction channel (along the Y direction) of the FinFET 200, and the central portion of the oxide layer 222 may be replaced by a high-k dielectric layer serving as the gate dielectric layer of the FinFET 200, which will be discussed in further detail below.

In some embodiments, the dummy gate stack 230 includes a dummy gate electrode 232, which will be removed in a later removal process, and spacer layers 234 extending along sidewalls of the dummy gate electrode 232. In some embodiments, the dummy gate electrode 232 may comprise a polysilicon material. Further, the dummy gate electrode 232 may be a polysilicon material doped with a uniform or non-uniform doping concentration. The dummy gate electrode 232 may be fainted using a suitable process such as ALD, CVD, physical vapor deposition (PVD), plating, or combinations thereof.

In some embodiments, the spacer layer 234 may include silicon oxide (SiO), silicon nitride (SiN), silicon oxynitride (SiON), or other suitable material. The spacer layer 234 may comprise a single layer or multilayer structure. In some embodiments, the spacer layer 234 may be formed by depositing a blanket layer of the spacer layer 234 by CVD, PVD, ALD, or other suitable technique, and performing an anisotropic etching process on the blanket layer to form the pair of the spacer layer 234 along the sidewalls of the gate electrode 232, as shown in the illustrated embodiment of FIG. 10A.

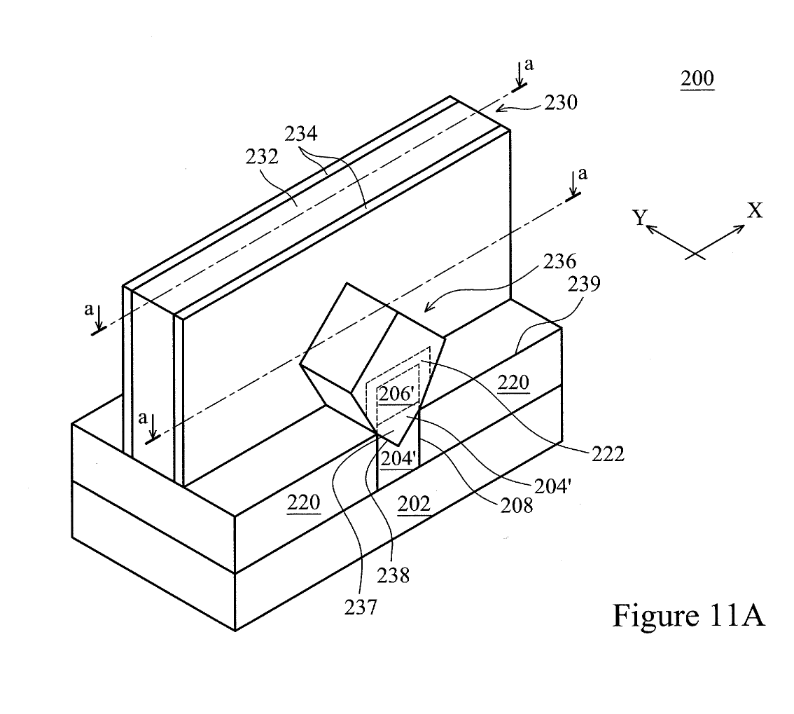

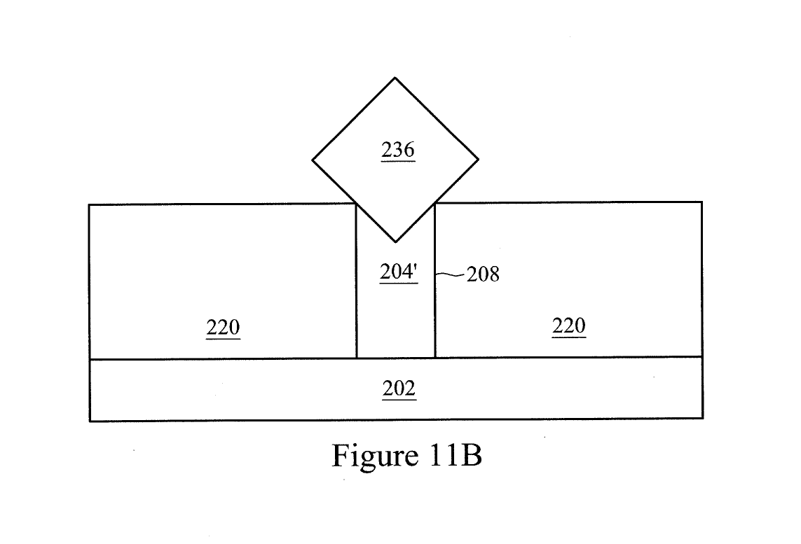

Corresponding to operation 120 of FIG. 1, FIG. 11A is a perspective view of the FinFET 200 including source/drain (S/D) features 236 formed on sides (along the Y direction) of the dummy gate stack 230, according to some embodiments, and FIG. 11B is a cross-sectional view of the FinFET 200 taken along line a-a of FIG. 11A. It is noted the line a-a of FIG. 11A is not taken across the dummy gate stack 230, but across the S/D feature 236. In some embodiments, the respective side portions of the oxide layer 222 and at least part of the upper fin 209 (the remaining portion of the Ge-based top layer 206′ and an upper portion of the remaining portion of the Si bottom layer 204′) are removed before the formation of the S/D features 236, so that the removed side are shown in dotted lines, respectively, in FIG. 11A. The formation of the S/D feature 236 will be briefly described as follows.

In some embodiments, the side portions of the oxide layer 220 not covered by the gate stack 230 are removed by one or more selective wet/dry etching processes, and the side portions of the upper fin 209 are removed by one or more other selective wet/dry etching processes so as to form respective recesses 237 on the sides of the dummy gate stack 230. In some embodiments, each recess 237 has a bottom surface 238. Such a recess 237 may be extended downwardly beneath a top surface 239 of the isolation feature 220, i.e., the bottom surface 238 is vertically lower than the top surface 239. Subsequently, the S/D features 236 are epitaxially grown from the fin 212 (e.g., the remaining portion of the Si bottom layer 204′ in the illustrated embodiments of FIGS. 11A and 11B) by using a low-pressure chemical vapor deposition (LPCVD) process and/or a metal-organic chemical vapor deposition (MOCVD) process.

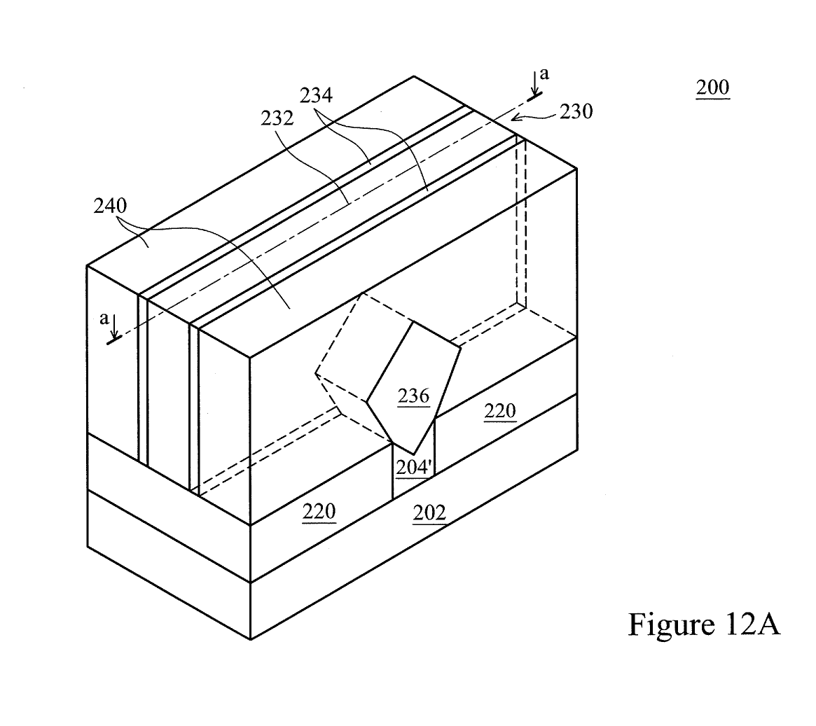

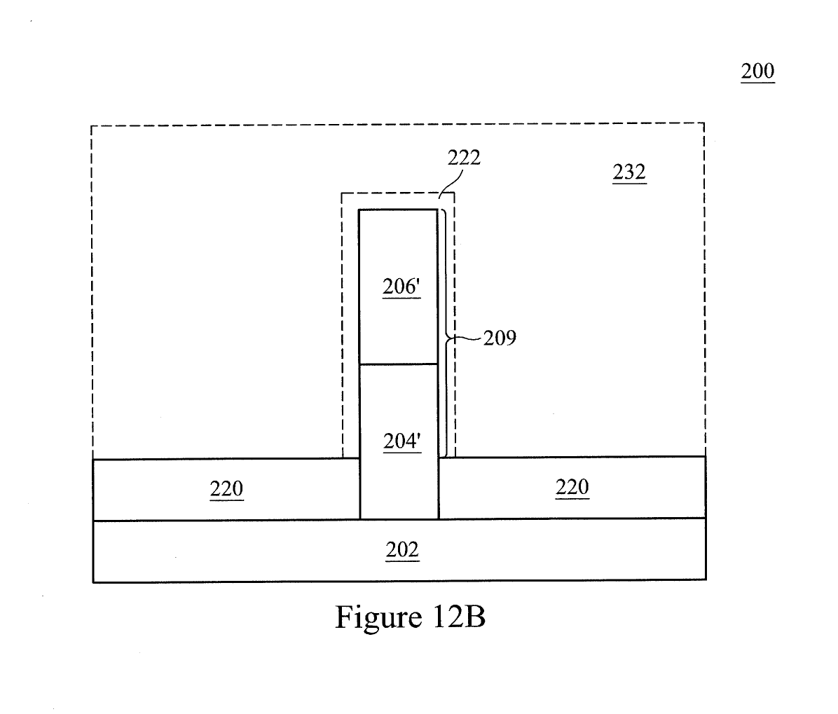

Corresponding to operation 122 of FIG. 1, FIG. 12A is a perspective view of the FinFET 200 with the dummy gate electrode 232 and the central portion of the oxide layer 222 that was overlaid by the dummy gate electrode 232 being removed, according to some embodiments, and FIG. 12B is a cross-sectional view of the FinFET 200 taken along line a-a of FIG. 12A. For purposes of illustration, the removed dummy gate electrode 232 and central portion of the oxide layer 222 are shown in dotted line. As shown, after the dummy gate electrode 232 and the central portion of the oxide layer 222 are removed, the central portion of the upper fin 209 (that was overlaid by the dummy gate electrode 232 and the central portion of the oxide layer 222) is exposed.

In some embodiments, prior to the dummy gate electrode 232 and the central portion of the oxide layer 222 being removed, a dielectric layer 240 may be formed over the S/D features 236 to protect the formed S/D features 236. Such a dielectric layer 240 may include a material that is selected from at least one of: silicon oxide, a low dielectric constant (low-k) material, or a combination thereof. The low-k material may include fluorinated silica glass (FSG), phosphosilicate glass (PSG), borophosphosilicate glass (BPSG), carbon doped silicon oxide (SiOₓC_{y}), Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, and/or other future developed low-k dielectric materials.

Further, in some embodiments, concurrently with or subsequently to the dummy gate electrode 232 and the central portion of the oxide layer 222 being removed, the spacer layer 234 may remain intact. The dummy gate electrode 232 and the central portion of the oxide layer 222 may be, respectively or concurrently, removed (etched) by one or more selective dry and/or wet etching processes until the central portion of the upper fin 209 that was covered by the dummy gate electrode 232 and the central portion of the oxide layer 222 is exposed. More specifically, in some embodiments, the wet etching process includes using diluted hydrofluoric acid (DHF), and/or an amine derivative etchant (e.g., NH₄OH, NH₃(CH₃)OH, TetraMethyl Ammonium Hydroxide (TMAH), etc.); and the dry etching process includes using a plasma of reactive gas that is selected from: fluorocarbons, oxygen, chlorine, boron trichloride, nitrogen, argon, helium, or a combination thereof.

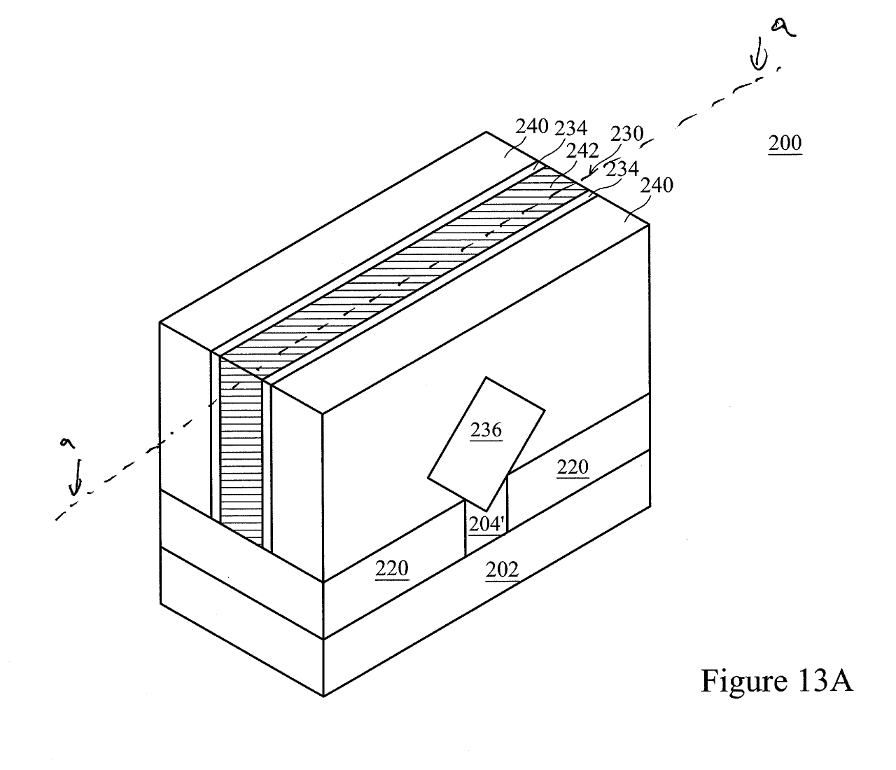

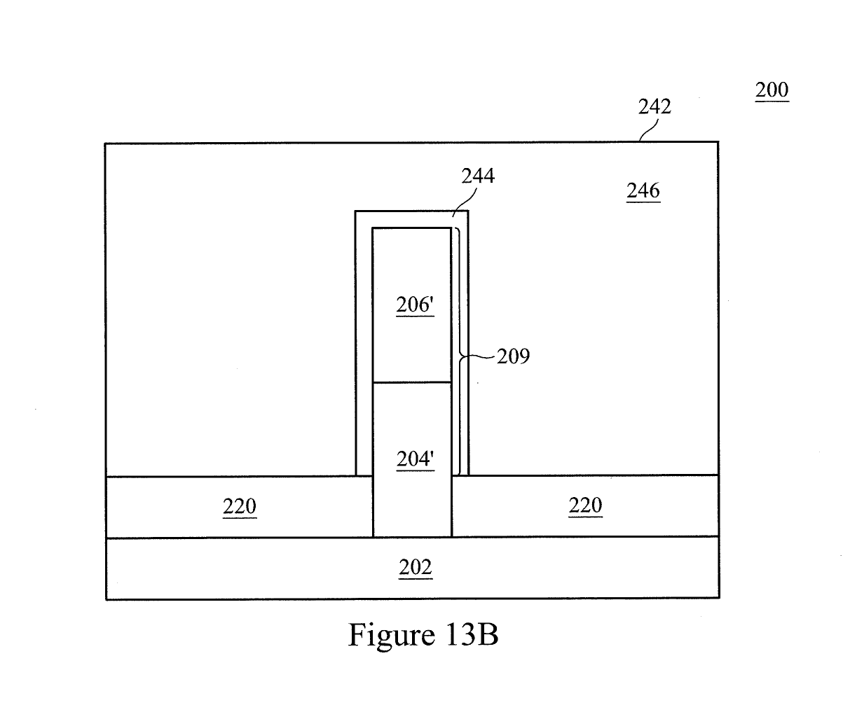

Corresponding to operation 124 of FIG. 1, FIG. 13A is a perspective view of the FinFET 200 including a gate feature 242 formed over the exposed portion (i.e., the central portion) of the upper fin 209, according to some embodiments, and FIG. 13B is a cross-sectional view of the FinFET 200 taken along line a-a of FIG. 13A. In some embodiments, the gate feature 242 may include a gate dielectric layer 244 and a conductive gate electrode 246. More specifically, as shown in the cross-sectional view of FIG. 13B, the central portion of the upper fin 209 is overlaid by the conductive gate electrode 246 with the gate dielectric layer 244 sandwiched therebetween.

In some embodiments, the gate dielectric layer 244 may be formed of a high-k dielectric material. Such a high-k dielectric material may have a “k” value greater than about 4.0, or even greater than about 7.0. In such embodiments, the high-k dielectric layer 244 may be formed of at least one material selected from: Al₂O₃, HfAlO, HfAlON, AlZrO, HfO₂, HfSiOₓ, HfAlOₓ, HfZrSiOₓ, HfSiON, LaAlO₃, ZrO₂, or a combination thereof. The high-k dielectric layer 242 may be formed using a suitable process such as ALD, CVD, PVD, plating, or combinations thereof.

In some embodiments, the conductive gate electrode 246 may include a metal material such as, for example, Al, Cu, W, Ti, Ta, TiN, TiAl, TiAlN, TaN, NiSi, CoSi, or combinations thereof. In some alternative embodiments, the conductive gate electrode 246 may include a polysilicon material, wherein the polysilicon material may be doped with a uniform or non-uniform doping concentration. The conductive gate electrode 246 may be formed using a suitable process such as ALD, CVD, PVD, plating, or combinations thereof.

As mentioned above with respect to FIGS. 4A and 4B, the Ge-based top layer 206 may include plural top layers stacked on top of one another, in accordance with some other embodiments. FIG. 14 illustrates a cross-sectional view of another exemplary FinFET 1400 including such plural top layers (e.g., 1411, 1412, 1413, 1414, 1415, 1416, 1417, 1418, etc.), at one of the various stages of fabrication, in accordance with some embodiments. As shown, the FinFET 1400 is substantially similar to the FinFET 200 shown in FIG. 13B except that the FinFET 1400's upper fin 1409 includes plural top layers (e.g., 1411 to 1418), instead of one single Ge-based layer 206′, overlying the upper portion of the remaining portion of the Si bottom layer 204′. Thus, some of the numerical references in FIG. 13B are continued to be used in the FinFET 1400 of FIG. 14, e.g., 202, 220, 242, 244, 246.

In some embodiments, the FinFET 1400 is made by the method 100 of FIG. 1 except that operation 106 may include alternately forming one or more Ge-based layers and Si layers, which will be discussed in further detail below. To form the FinFET 1400, operation 106 of FIG. 1 may include forming a first layer formed of Ge over the Si bottom layer 204 (FIGS. 4A and 4B), a second layer formed of Si over the first Ge layer, a third layer formed of Ge over the second Si layer, a fourth layer formed of Si over the third Ge layer, and so on. As such, in some embodiments, there may be a plurality of periodic layers each formed of a respective material, e.g., Si or Ge, disposed over the Si bottom layer 204. Similar to the formation of the Si bottom layer 204 with respect to FIGS. 3A and 3B, and Ge-based top layer 206 with respect to FIGS. 4A and 4B, each of the plurality of periodic layers, disposed above the Si bottom layer 204, may be formed by using chemical vapor deposition (CVD) technique such as vapor-phase epitaxy (VPE), and/or other suitable processes known in the art, e.g., molecular beam epitaxy (MBE) technique, wafer bonding technique, etc. As such, a respective thickness of each Ge layer of the plurality of periodic layers can be accurately controlled up to about 3 nm, while a respective thickness of each Si layer of the plurality of periodic layers can be accurately controlled to any desired value.

Following the remaining operations 108-124 of the method 100 of FIG. 1, the FinFET 1400 may be made as shown in FIG. 14. In the illustrated embodiment of FIG. 14, the first top layer 1411 is formed of Ge; the second top layer 1412 is formed of Si; the third top layer 1413 is formed of Ge; the fourth top layer 1414 is formed of Si; the fifth top layer 1415 is formed of Ge; the sixth top layer 1416 is formed of Si; the seventh top layer 1417 is formed of Ge; and the eighth top layer 1418 is formed of Si. Although a total of eight top layers (1411 to 1418) formed above the remaining portion of Si bottom layer 204′ in the upper fin 1409, in some other embodiments, any desire number of top layers can be formed over the remaining portion of Si bottom layer 204′ in the upper fin 1409 while remaining within the scope of the present disclosure.

In an embodiment, a semiconductor device includes a fin-like structure. The fin-like structure includes a bottom layer formed of silicon and at least a top layer formed of germanium. The semiconductor device further includes a gate stack feature overlaying a central upper portion of the fin-like structure, wherein the gate stack is in contact with a top surface and sidewalls of the top layer, and at least part of sidewalls of the bottom layer.

In another embodiment, a semiconductor device includes a fin-like structure and a gate stack feature. The fin-like structure includes a bottom layer formed of silicon, a first top layer overlaying the bottom layer that is formed of germanium, and a second top layer overlaying the first top layer that is formed of silicon. The gate stack feature overlays a central upper portion of the fin-like structure, wherein the gate stack is in contact with a top surface and sidewalls of the second top layer, sidewalls of the first top layer, and at least part of sidewalls of the bottom layer.

Yet in another embodiment, a method includes: forming a silicon layer over a substrate; forming a germanium layer over the silicon bottom layer; forming a fin that protrudes beyond a major surface of the substrate, wherein the fin comprises a portion of the silicon layer as a bottom layer and a portion of the germanium layer as a top layer; and forming a gate stack feature overlaying a central upper portion of the fin, wherein the gate stack is in contact with a top surface and sidewalls of the top layer, and at least part of sidewalls of the bottom layer.

The foregoing outlines features of several embodiments so that those ordinary skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a fin-like structure, the fin-like structure comprising a bottom layer formed of silicon and a plurality of layers of semiconductor material epitaxially grown on said silicon bottom layer, said plurality of layers comprising at least four alternating single layers of germanium and silicon semiconductor materials; and
a gate stack feature overlaying a central upper portion of the fin-like structure,
wherein the gate stack is in contact with a top surface and sidewalls of the top layer, and at least part of sidewalls of the bottom layer.

2. The device of claim 1, wherein the gate stack further comprises:
a gate dielectric layer; and
a conductive gate electrode disposed above the gate dielectric layer,
wherein the gate dielectric layer is in direct contact with the top surface and sidewalls of the top layer, and at least part of the sidewalls of the bottom layer.

3. The device of claim 2, wherein the gate dielectric layer is formed of a high-k dielectric material.

4. (canceled)

5. The device of claim 1, further comprising:
at least one isolation feature disposed below the gate stack feature and in contact with a lower portion of the fin-like structure.

6. The device of claim 1, further comprising:
at least a source/drain feature disposed beside the gate stack feature.

7-20. (canceled)

21. A semiconductor device, comprising:
a fin-like structure, the fin-like structure comprising a bottom layer formed of silicon and a first top layer that is formed of silicon-germanium alloy, and a plurality of layers of semiconductor material epitaxially grown on said silicon germanium alloy layer, said plurality of layers comprising at least four alternating single layers of germanium and silicon semiconductor materials; and
a gate stack overlaying a central upper portion of the fin-like structure, wherein the gate stack is in contact with a top surface and sidewalls of the top layer, and at least part of sidewalls of the bottom layer.

22. The device of claim 21, wherein the gate stack further comprises:
a gate dielectric layer; and
a conductive gate electrode disposed above the gate dielectric layer,
wherein the gate dielectric layer is in direct contact with the top surface and sidewalls of the top layer, and at least part of the sidewalls of the bottom layer.

23. The device of claim 22, wherein the gate dielectric layer is formed of a high-k dielectric material.

24. The device of claim 21, further comprising:
at least one isolation feature disposed below the gate stack feature and in contact with a lower portion of the fin-like structure.

25. The device of claim 21, further comprising:
at least a source/drain feature disposed beside the gate stack feature.
